(19) United States
(12) Patent Application Publication
(10) Pub. No.: US 2025/0015233 A1
(43) Pub. Date: Jan. 9, 2025

(54) SEMICONDUCTOR LIGHT EMITTING ELEMENT AND LIGHT EMITTING DEVICE

(71) Applicant: STANLEY ELECTRIC CO., LTD., Tokyo (JP)

(72) Inventors: Maiko TANABE, Tokyo (JP); Daizo KAMBARA, Tokyo (JP); Yoichi SHIMODA, Tokyo (JP)

(73) Assignee: STANLEY ELECTRIC CO., LTD., Tokyo (JP)

(21) Appl. No.: 18/759,892

(22) Filed: Jun. 30, 2024

(30) Foreign Application Priority Data
Jul. 3, 2023 (JP) 2023-109538

(51) Int. Cl. H01L 33/38; H01L 25/075; H01L 33/50; H01L 33/62

(52) U.S. Cl. CPC H01L 33/387; H01L 25/0753; H01L 33/502; H01L 33/505; H01L 33/62

(57) ABSTRACT

A semiconductor light emitting element (10) includes flat plate-shaped translucent element substrate (11) with two main surfaces (11A, 11B) facing each other, light emitting semiconductor layer (12) formed on one main surface (11A) of element substrate (11) and in which n-type semiconductor layer (13), light emitting layer (14), and p-type semiconductor layer (15) are laminated, n-electrode (16) connected to n-type semiconductor layer (13) through at least one hole portion (12A) leading to n-type semiconductor layer (13) and provided on p-type semiconductor layer (15) being electrically separated from p-type semiconductor layer (15) by insulating film (18), first element electrode (19) electrically connected to n-electrode (16) and provided to extend in first direction, and second element electrode (20) electrically connected to p-type semiconductor layer (15) and provided to extend in first direction while being spaced apart from first element electrode (19), where thickness of element substrate (11) is 100 μm or less.

### BACKGROUND OF THE INVENTION

### 1. Field of the Invention

The present invention relates to a light emitting element and a light emitting device, and more particularly to a semiconductor light emitting element such as a light emitting diode (LED) and a light emitting device on which the semiconductor light emitting element is mounted.

### 2. Description of the Related Art

A light emitting device on which a semiconductor light emitting element is mounted is used for various illumination or display devices, and the like. In particular, in recent years, the light emitting device on which the semiconductor light emitting element is mounted is required to be thinned in order to further achieve space saving.

For example, Japanese Patent Application Laid-Open No. 2010-219324 discloses a light emitting device that includes a mounting substrate having a base material and a wiring layer for external connection, and a light emitting element provided on a top surface of the mounting substrate and having both a first conductive type (negative) and a second conductive type (positive) electrodes.

### CITATION LIST

### Patent Literature

Patent Literature 1: Japanese Patent Application Laid-Open No. 2010-219324

### SUMMARY OF THE INVENTION

However, in the light emitting device that includes a mounting substrate having a base material and a wiring layer for external connection, and a light emitting element provided on a top surface of the mounting substrate and having both electrodes of a first conductive type (negative) and a second conductive type (positive), there is a problem in reliability, such as a risk of stress being concentrated between both electrodes, causing damage or deterioration of the semiconductor light emitting element.

The present invention has been made in view of the above points, and an object thereof is to provide a semiconductor light emitting element in which a luminous flux is improved when being used as a light emitting device, or a light emitting device in which reliability is improved and a luminous flux is improved while achieving thinning.

A semiconductor light emitting element according to Embodiment 1 of the present invention includes a flat plate-shaped translucent element substrate that has two main surfaces facing each other, a light emitting semiconductor layer configured to be formed on one main surface of the element substrate and in which an n-type semiconductor layer, a light emitting layer, and a p-type semiconductor layer are laminated, an n-electrode configured to be connected to the n-type semiconductor layer through at least one hole portion leading to the n-type semiconductor layer and provided on the p-type semiconductor layer to be electrically separated from the p-type semiconductor layer by an insulating film, a first element electrode configured to be electrically connected to the n-electrode and provided to extend in a first direction, and a second element electrode configured to be electrically connected to the p-type semiconductor layer and provided to extend in the first direction while being spaced apart from the first element electrode, in which a thickness of the element substrate is 100 μm or less.

### BRIEF DESCRIPTION OF THE DRAWINGS

FIG. 1A is a plan view illustrating a top surface of a semiconductor light emitting element according to the present invention.

FIG. 1B is a cross-sectional view of the semiconductor light emitting element taken along the line A-A illustrated in FIG. 1A.

FIG. 1C is a cross-sectional view of the semiconductor light emitting element taken along the line B-B illustrated in FIG. 1A.

FIG. 1D is a cross-sectional view of the semiconductor light emitting element taken along the line C-C illustrated in FIG. 1A.

FIG. 1E is a plan view illustrating a bottom surface of the semiconductor light emitting element according to the present invention.

FIG. 2A is a plan view illustrating a top surface of a light emitting device according to the present invention.

FIG. 2B is a cross-sectional view of the light emitting device taken along the line D-D illustrated in FIG. 2A.

FIG. 2C is a plan view illustrating a bottom surface of the light emitting device according to the present invention.

FIG. 2D is a plan view illustrating a top surface of the light emitting device according to the present invention, and is a view illustrating a state where a coating member is made transparent.

FIG. 3 is a plan view illustrating a top surface of a device substrate according to the present invention.

FIG. 4 is a flowchart illustrating a method of manufacturing the light emitting device according to the present invention.

FIG. 5A is a plan view illustrating a top surface of a manufacturing step S1 of the light emitting device according to the present invention.

FIG. 5B is a plan view illustrating a top surface of a manufacturing step S2 of the light emitting device according to the present invention.

FIG. 5C is a plan view illustrating a top surface of a manufacturing step S3 of the light emitting device according to the present invention.

FIG. 5D is a plan view illustrating a top surface of a manufacturing step S4 of the light emitting device according to the present invention.

FIG. 5E is a plan view illustrating a top surface of a manufacturing step S5 of the light emitting device according to the present invention.

FIG. 6A is a plan view illustrating a top surface of a light emitting device according to Embodiment 3, and is a view illustrating a state where a coating member is made transparent.

FIG. 6B is a view illustrating a wiring pattern of a circuit substrate 60 on which the light emitting device according to Embodiment 3 is mounted.

FIG. 6C is a view illustrating a modification example of a wiring pattern of the circuit substrate 60 on which the light emitting device according to Embodiment 3 is mounted.

FIG. 7 is a plan view illustrating a top surface of a device substrate of the light emitting device according to Embodiment 3.

### DESCRIPTION OF THE PREFERRED EMBODIMENTS

Hereinafter, preferred embodiments of the present invention will be described, but may be appropriately modified and combined. In addition, in the following descriptions and the accompanying drawings, substantially the same or equivalent parts will be described with the same reference numerals. First, the description will be made for the semiconductor light emitting element and then for the light emitting device.

### Embodiment 1

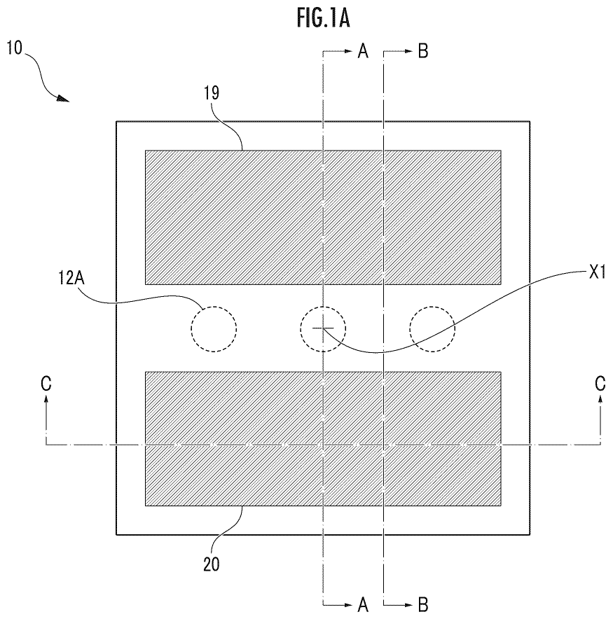

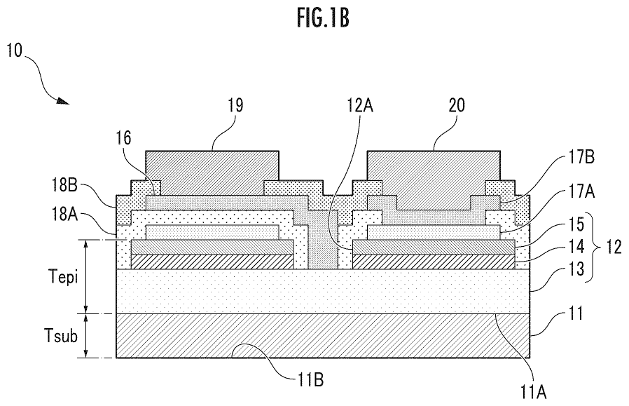

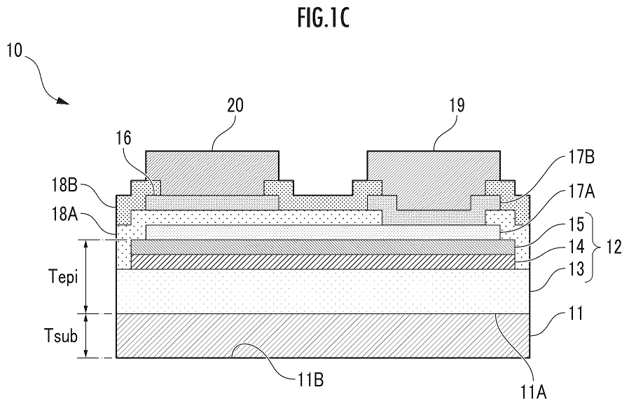

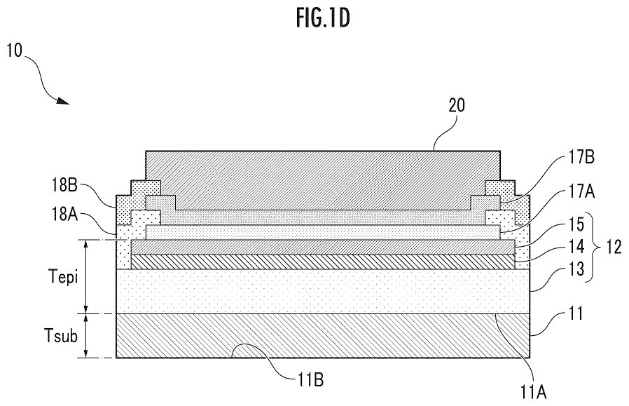

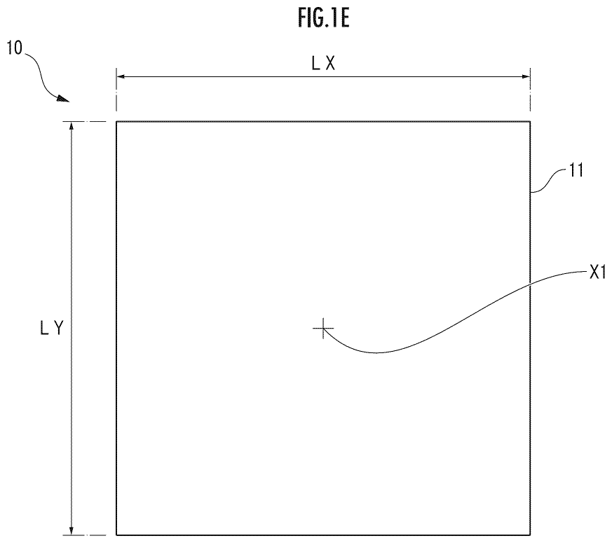

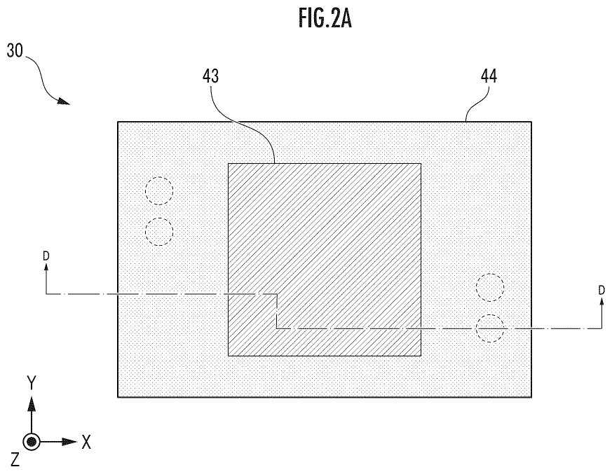

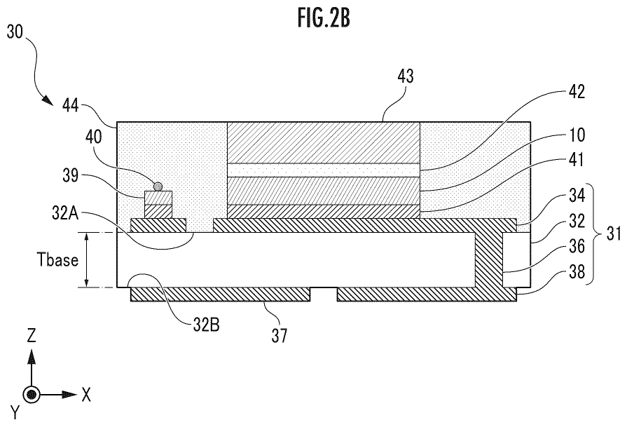

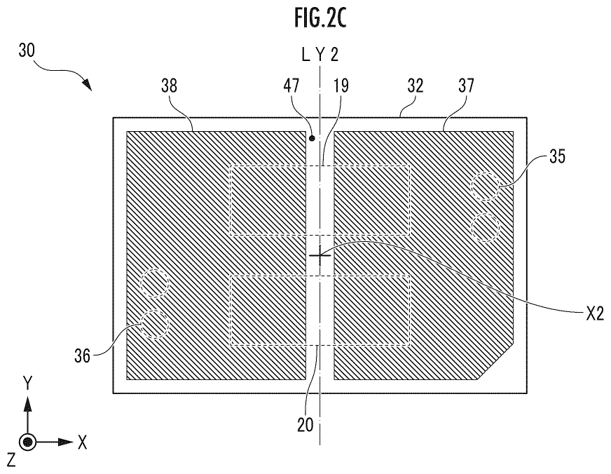

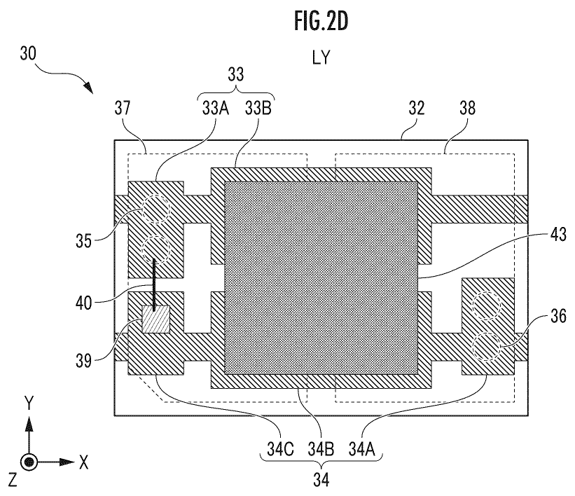

Embodiment 1 is a semiconductor light emitting element 10 used in a light emitting device 30 illustrated in FIGS. 2A-2D. FIG. 1A is a plan view illustrating a top surface of the semiconductor light emitting element 10 according to the present invention. FIG. 1B is a cross-sectional view of the semiconductor light emitting element 10 taken along the line A-A illustrated in FIG. 1A, FIG. 1C is a cross-sectional view of the semiconductor light emitting element 10 taken along the line B-B illustrated in FIG. 1A, and FIG. 1D is a cross-sectional view of the semiconductor light emitting element 10 taken along the line C-C illustrated in FIG. 1A. FIG. 1E is a plan view illustrating a bottom surface of the semiconductor light emitting element 10 according to the present invention.

In FIG. 1A, hole portions 12A are illustrated by broken lines in order to clarify the disposition relationship of the hole portions 12A included in a light emitting semiconductor layer 12, which will be described later.

In the description of the semiconductor light emitting element 10, a direction where the light emitting semiconductor layer 12 is provided with respect to the element substrate 11 is referred to as an upward direction, and an opposite direction is referred to as a downward direction.

As illustrated in FIGS. 1A to 1E, the semiconductor light emitting element 10 includes a rectangular flat plate-shaped element substrate 11 having two parallel main surfaces, and a light emitting semiconductor layer 12 on which a semiconductor crystal is laminated is provided on a top surface of the element substrate 11. In addition, two electrodes, an n-electrode 16 and a p-electrode 17, of which a part is insulated by an insulating film 18, are disposed on the top surface of the light emitting semiconductor layer 12, and a first element electrode 19 and a second element electrode 20 provided extending in one direction (left-right direction in FIG. 1A) on the top surfaces of the two electrodes and each of which has substantially the same size and a rectangular shape are provided in parallel so as to substantially cover the top surface of the semiconductor light emitting element 10. That is, a main light output surface of the semiconductor light emitting element 10 according to the present embodiment is a bottom surface 11B side of the element substrate 11.

### (Element Substrate)

As illustrated in FIG. 1B, the element substrate 11 is a rectangular flat plate having a top surface 11A serving as a first main surface, and a bottom surface (rear surface) 11B serving as a second main surface, which face each other in parallel. In addition, the element substrate 11 has a transmittance for transmitting the emitted light emitted from the light emitting semiconductor layer 12. In addition, the element substrate 11 has a function as a framework (support body) of the semiconductor light emitting element 10.

As the element substrate 11, a sapphire (Al₂O₃) single crystal is used. The bending strength of the sapphire single crystal is 690 MPa, and the sapphire single crystal has a high strength even in a case where the element substrate 11 is thinned. In the present embodiment, the thickness Tsub of the element substrate 11 is reduced to 100 μm to reduce the thickness of the entire semiconductor light emitting element 10. However, when the thickness is excessively small, the function as the framework is impaired, and thus the thickness is preferably in a range of 40 μm to 100 μm. For example, when the thickness is less than 40 μm, occurring defect such as a failure to light increase during the manufacturing or use of the semiconductor light emitting element 10 and the light emitting device 30. In addition, the framework strength is able to be improved when the thickness is more than 100 μm, but the light emitting device 30 is not able to be thinned. As the element substrate 11, an aluminum nitride (AlN) single crystal, a silicon carbide (SiC) single crystal, a gallium nitride (GaN) single crystal, or the like is also able to be used.

A rough surface layer or an anti-reflection coating (AR coating) that improves light extraction efficiency is able to be provided on the bottom surface 11B of the element substrate 11.

### (Light Emitting Semiconductor Layer)

As illustrated in FIG. 1B, the light emitting semiconductor layer 12 is a laminated structure of a semiconductor crystal in which an n-type semiconductor layer 13 which is a main conduction type is an n-type semiconductor layer, a light emitting layer 14 including a quantum well layer structure, and a p-type semiconductor layer 15 which is a main conduction type is a p-type semiconductor layer are laminated in this order and having a total thickness Tepi of 3 μm to 5 μm. In addition, the light emitting semiconductor layer 12 is a crystal growth layer in which the element substrate 11 is grown as a growth substrate, and is supported by being integrated with the element substrate 11.

The n-type semiconductor layer 13 of the light emitting semiconductor layer 12 has the same size as that of the element substrate 11 in a top view. In addition, the light emitting layer 14 and the p-type semiconductor layer 15 have an outer shape having one size smaller than the outer shape of the n-type semiconductor layer 13. That is, an exposed portion of the n-type semiconductor layer 13 surrounds the light emitting layer 14 and the p-type semiconductor layer 15 in a frame shape over the entire periphery.

In addition, as illustrated in FIG. 1A, the light emitting semiconductor layer 12 has three hole portions 12A leading to the n-type semiconductor layer 13 from the top surface of the p-type semiconductor layer 15. The three hole portions 12A are arranged in a straight line at equal intervals, and a central hole portion is disposed at the center X1 of the light emitting semiconductor layer 12. In addition, the three hole portions 12A are arranged in parallel to a set of parallel sides of the element substrate 11.

In the present embodiment, the number of the hole portions 12A is set to three, but may be one or two, or four or more. In addition, the hole portions 12A may be arranged in parallel in two rows.

The light emitting semiconductor layer 12 is made of a gallium nitride (GaN)-based compound semiconductor, and radiates blue light. The p-type semiconductor layer 15 or the n-type semiconductor layer 13 may include layers such as an un-doped layer, a strained-layer superlattice (SLS) layer, an electron blocking layer (EBL), a contact layer, or the like in addition to a layer doped with an impurity exhibiting a main conduction type.

(n-Electrode)

As illustrated in FIG. 1B, the n-electrode 16 is provided on the top surface of a first p-electrode 17A on the left side partitioned by the hole portions 12A arranged in a straight line, through a first insulating film 18A. In addition, a part of the n-electrode 16 is electrically connected to the n-type semiconductor layer 13 through the hole portion 12A in which the wall surface is insulated with the first insulating film 18A.

The n-electrode 16 is formed by laminating titanium (Ti) and gold (Au) in this order. Hereinafter, the layers laminated in order will be referred to as Ti/Au. As the n-electrode 16, Ti/aluminum (Al), Ti/Al/platinum (Pt)/Au, Ti/Pt/Au, Ti/rhodium (Rh)/Au, or the like is also able to be used.

(p-Electrode)

As illustrated in FIG. 1B, the p-electrode 17 is made of a first p-electrode 17A and a second p-electrode 17B. The first p-electrode 17A is provided on substantially the entire surface of the p-type semiconductor layer 15. In addition, the second p-electrode 17B is provided on the top surface of the first p-electrode 17A on the right side partitioned by the hole portions 12A arranged in a straight line.

The first p-electrode 17A is formed by laminating nickel (Ni)/Au. As the first p-electrode 17A, indium tin oxide (ITO), Ni/Pt/Au, Ni/palladium (Pd)/Au, Ni/silver (Ag)/Pt/Au, Ni/Pt/Al/Pt/Au, or the like is also able to be used.

The second p-electrode 17B is formed by laminating Ti/Au. As the second p-electrode 17B, Ti/Al, Ti/Al/Pt/Au, Ti/Pt/Au, Ti/Rh/Au, or the like is also able to be used, similar to the n-electrode 16.

### (Insulating Film)

As illustrated in FIG. 1B, the insulating film 18 is made of a first insulating film 18A and a second insulating film 18B.

The first insulating film 18A covers to protect and insulate the n-type semiconductor layer 13, the light emitting layer 14, and the p-type semiconductor layer 15. In addition, the first insulating film 18A covers to protect and insulate the side surface and the bottom surface of a part of the first p-electrode 17A in contact with the p-type semiconductor layer 15.

The second insulating film 18B covers to protect and insulate the n-electrode 16 and the second p-electrode 17B, except for a part of the first insulating film 18A.

As the insulating film 18, silicon dioxide (SiO₂) is used. As the insulating film 18, an insulating metal oxide such as titanium dioxide (TiO₂), hafnium oxide (HfO₂), alumina (Al₂O₃), or the like is also able to be used.

### (Element Electrode)

The first element electrode 19 and the second element electrode 20 (hereinafter, both are referred to as an element electrode in a case where both are not distinguished) are provided on the top surface of the semiconductor light emitting element 10 as illustrated in FIG. 1A and FIG. 1B. The element electrodes 19 and 20 have a substantially same size rectangular shape having a pair of parallel long sides and the other pair of parallel short sides, and are provided in parallel and spaced apart from three hole portions 12A arranged in a straight line. In addition, the element electrode is provided inside and spaced apart from the outer peripheral edge of the semiconductor light emitting element 10. The two element electrodes 19 and 20 are bonding electrodes for electrically bonding external wiring to the semiconductor light emitting element 10. Such a semiconductor light emitting element 10 is a flip chip-connection type light emitting element that does not require a wire connection.

The first element electrode 19 (cathode) is connected to the n-type semiconductor layer 13 through the n-electrode 16, and the second element electrode 20 (anode) is connected to the p-type semiconductor layer 15 through the p-electrode 17. Therefore, by applying a voltage to the first element electrode 19 and the second element electrode 20, a current is able to be passed through the light emitting semiconductor layer 12, and the semiconductor light emitting element 10 is able to emit light.

As the element electrode, Ni/Au is used. As the element electrode, a highly conductive metal such as Ti/Au and Ti/Ni/Au is also able to be used.

### Comparative Example 1

Next, Comparative Example 1 will be described. Comparative Example 1 is a semiconductor light emitting element in which the thickness Tsub of the element substrate 11 according to Embodiment 1 is increased from 100 μm to 200 μm. The element substrate has the same configuration as that of the semiconductor light emitting element 10 according to Embodiment 1, except for the thickness.

### (Comparison of Light Output)

The semiconductor light emitting element 10 according to Embodiment 1 and the semiconductor light emitting element according to Comparative Example 1 were bonded to a circuit substrate through a gold-tin bonding member, and a current was passed through each semiconductor light emitting element to compare the light output. As a result, in a case where the light output according to Comparative Example 1 was set to 100%, the light output according to Embodiment 1 was 98%. That is, the light output of the semiconductor light emitting element 10 according to Embodiment 1 is 2% lower than the light output of the semiconductor light emitting element according to Comparative Example 1.

The decrease in light output is due to a decrease in the area of the light output surface by thinning the element substrate 11. Therefore, the light output is further reduced as the thickness of the element substrate 11 is reduced to 70 μm and 40 μm. In addition, the mechanical strength of the semiconductor light emitting element 10 is also reduced at the same time.

Hereinbefore, the semiconductor light emitting element 10 according to Embodiment 1 is able to be thinned while reducing the light output and the mechanical strength in a single stage.

### (Method of Manufacturing Semiconductor Light Emitting Element)

Next, a method of manufacturing a semiconductor light emitting element 10 according to Embodiment 1 will be described.

First, as the element substrate 11, an element substrate with a light emitting semiconductor layer 12 in which a gallium nitride-based n-type semiconductor layer 13, a light emitting layer 14, and a p-type semiconductor layer 15 are laminated on one surface of a sapphire single crystal substrate by epitaxial growth is prepared (SD1).

A resist mask is formed on a portion of the element substrate 11 with the light emitting semiconductor layer 12, which is a light emitting region, and etching is performed by reactive ion etching (RIE) until the n-type semiconductor layer 13 is exposed in a portion other than the resist mask. Thereafter, the resist mask is removed to form the light emitting region having the hole portion 12A (SD2).

A resist mask in which a portion to be the first p-electrode 17A is exposed is formed on the top surface of the p-type semiconductor layer 15 in the light emitting region, and Ni and Au are evaporated in this order as the first p-electrode 17A using an electron beam (EB) evaporation device. Thereafter, the resist mask is removed to form the first p-electrode 17A (SD3).

A SiO₂ film is formed on the entire surface of the element substrate on which the first p-electrode 17A is formed, as an insulating film, by a sputtering device. Next, a resist mask is formed on a portion other than the formation of the bottom surface portion of the hole portion 12A and the second p-electrode 17B, and the insulating films on the bottom surface portion of the hole portion 12A and the second p-electrode 17B forming portion are etched and removed with a fluorine acid buffer solution to form the first insulating film 18A (SD4).

A resist mask is formed on a portion other than the portion to be the n-electrode 16 and the second p-electrode 17B, and Ti and Au are evaporated in this order as the n-electrode 16 and the second p-electrode 17B using the EB evaporation device.

Thereafter, the resist mask is removed to form the n-electrode 16 and the second p-electrode 17B (SD5).

A SiO₂ film is formed on the entire surface of the element substrate on which the n-electrode 16 and the second p-electrode 17B are formed, as an insulating film, by a sputtering device. Next, a resist mask is formed on a portion other than a portion where the first element electrode 19 and the second element electrode 20 are formed, and the insulating films of the n-electrode 16 and the second p-electrode 17B forming portion are etched and removed with a fluorine acid buffer solution to form the second insulating film 18B (SD6).

A resist mask is formed on a portion other than a portion to be the first element electrode 19 and the second element electrode 20, and Ti and Au are evaporated in this order as the element electrodes using the EB evaporation device. Thereafter, the resist mask is removed to form the first element electrode 19 and the second element electrode 20 (SD7).

Next, the sapphire single crystal substrate of the element substrate on which the first element electrode 19 and the second element electrode 20 are formed is thinned to 100 μm using a grinding and polishing device to form the element substrate 11 (SD8). In order to thin the element substrate 11 to 70 μm, 40 μm, or the like, the amount of grinding and polishing of the sapphire single crystal substrate in this step may be increased. In addition, in order to form the semiconductor light emitting element according to Comparative Example 1 in which the element substrate 11 has the thickness of 200 μm, the amount of grinding and polishing may be reduced.

The laser scribing is performed along the contour line of each of the semiconductor light emitting elements 10 from the surface side (rear surface side) of the element substrate 11, and the element is individualized into one unit to form the semiconductor light emitting element 10 (SD9).

### Embodiment 2

Next, a light emitting device 30 according to Embodiment 2 will be described. FIG. 2A is a plan view illustrating a top surface of the light emitting device 30 according to the present invention. FIG. 2B is a cross-sectional view of the light emitting device 30 taken along the line D-D illustrated in FIG. 2A, and FIG. 2C is a plan view illustrating a bottom surface of the light emitting device 30 according to the present invention. FIG. 2D is a plan view illustrating a top surface of the light emitting device 30 according to the present invention, and is a view illustrating a state where a coating member 44 is made transparent (state of being removed).

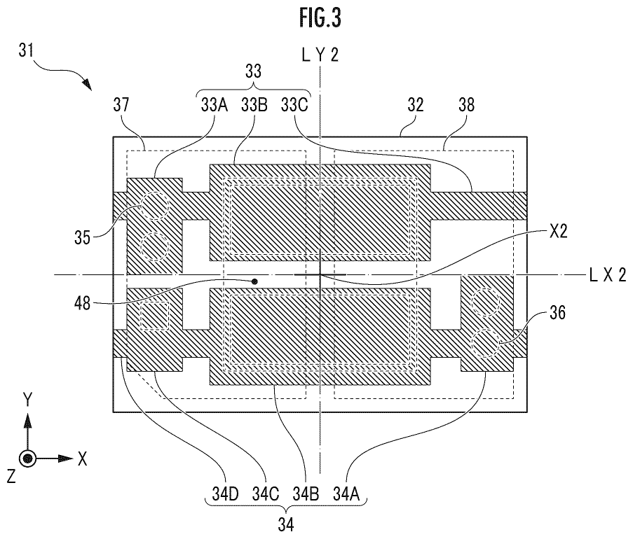

FIG. 3 is a plan view illustrating a top surface of a device substrate 31. In FIG. 2C, a first conduction via 35 and a second conduction via 36, and the first element electrode 19 and the second element electrode 20 are illustrated by broken lines in order to clarify the disposition relationship between the first element electrode 19 and the second element electrode 20, the first conduction via 35 and the second conduction via 36, and the first mounting electrode 37 and the second mounting electrode 38, which will be described later.

Furthermore, in FIG. 2D, the first mounting electrode 37 and the second mounting electrode 38 are illustrated by broken lines, and in FIG. 3, the first element electrode 19 and the second element electrode 20, and the first mounting electrode 37 and the second mounting electrode 38 are illustrated by broken lines in order to clarify the disposition relationship between the first element electrode 19 and the second element electrode 20, and the first mounting electrode 37 and the second mounting electrode 38.

In the description of the light emitting device 30, a direction where the semiconductor light emitting element 10 is provided with respect to the device substrate 31 is referred to as an upward direction, and an opposite direction is referred to as a downward direction. The XYZ coordinates are noted in each of the figures.

As illustrated in FIGS. 2A and 2B, in the light emitting device 30, the semiconductor light emitting element 10 and the protective element 39 are bonded to each other through the bonding member 41 on the top surface (+Z direction) of the rectangular flat plate-shaped device substrate 31. In addition, a phosphor plate 43 is adhered to the top surface of the semiconductor light emitting element 10 through a translucent adhesive member 42. In addition, the top surface 32A of the device substrate 31 and the side surfaces of the semiconductor light emitting element 10 and the phosphor plate 43 are covered with a light-shielding coating member 44. Therefore, the top surface of the exposed phosphor plate 43 is the light output surface of the light emitting device 30.

### (Device Substrate)

As illustrated in FIGS. 2B to 2D and 3, the device substrate 31 is a rectangular flat plate having a pair of long sides (sides in the X axis direction) that face each other in parallel and the other pair of short sides (sides in the Y axis direction) that face each other in parallel and are orthogonal to the pair of long sides, in a top view. The device substrate 31 includes a base body 32 having a top surface 32A which is a first main surface and a bottom surface 32B which is a second main surface facing each other, and the first wiring electrode 33 and the second wiring electrode 34 are provided on the top surface 32A of the base body 32, and the first mounting electrode 37 and the second mounting electrode 38 are provided on the bottom surface 32B. In addition, the first conduction via 35 and the second conduction via 36 that penetrate the base body 32 up and down are provided. Hereinafter, in a case where the first wiring electrode 33 and the second wiring electrode 34 are not distinguished, the electrodes will be referred to as the “wiring electrode”, in a case where the first mounting electrode 37 and the second mounting electrode 38 are not distinguished, the electrodes will be referred to as the “mounting electrode”, and in a case where the first conduction via 35 and the second conduction via 36 are not distinguished, the vias will be referred to as the “conduction via”.

As the base body 32, an aluminum nitride (AlN)-based ceramic substrate having a thickness Tbase of 70 μm is used. An aluminum nitride (AlN)-based ceramic is an insulating ceramic having excellent thermal conductivity and bending strength, with a thermal conductivity of 180 to 220 W/mK and a bending strength of 300 to 350 MPa. From the viewpoint of making the light emitting device 30 thin, it is preferable that the thickness of the base body 32 is thin, and when the strength as the base body is taken into consideration, the thickness is preferably 30 μm to 120 μm. As the base body 32, a silicon nitride (Si₃N₄)-based ceramic or the like is also able to be used.

As illustrated in FIG. 3, the first wiring electrode 33 (cathode) is provided on one surface (surface in the +Y direction in FIG. 3) of the device substrate 31 that is divided by a line segment LX2 passing through the midpoint X2 and parallel to the long side of the device substrate 31. In addition, the first wiring electrode 33 includes a first land 33A and a first element placing region 33B. The first element placing region 33B has a rectangular shape including the element electrode 19 (cathode) of the semiconductor light emitting element 10, and is provided at the center of the device substrate 31 so that the long side is along the line segment LX2. In addition, the first land 33A is provided at the end of one surface spaced apart from the first element placing region 33B. The first element placing region 33B and the first land 33A are connected by a first band portion 33C parallel to the line segment LX2.

The second wiring electrode 34 (anode) is provided on the other surface (surface in the −Y direction in FIG. 3) of the device substrate 31 that is divided by a line segment LX2 passing through the midpoint X2 and parallel to the long side of the device substrate 31. In addition, the second wiring electrode 34 includes a second land 34A, a second element placing region 34B, and a protective element placing region 34C. The second element placing region 34B has a rectangular shape including the element electrode 20 (anode) of the semiconductor light emitting element 10, and is provided at the center of the device substrate 31 so that the long side is along the line segment LX2. In addition, the second land 34A is provided at the end of the other surface that does not face the first land 33A. In addition, the protective element placing region 34C is provided at the end of the other surface facing the first land 33A. The second element placing region 34B, the second land 34A, and the protective element placing region 34C are connected by a second band portion 34D parallel to the line segment LX2.

Each of the short sides of the first element placing region 33B of the first wiring electrode 33 and the second element placing region 34B of the second wiring electrode 34 is aligned with each other in a top view (XY plane). In other words, the outer edge obtained by combining the first element placing region 33B and the second element placing region 34B has a rectangular shape and has a size including the semiconductor light emitting element 10.

The first mounting electrode 37 (cathode) is provided on one surface (surface in the +X direction in FIG. 2C) of the device substrate 31 that is divided by a line segment LY2 passing through the midpoint X2 and parallel to the short side of the device substrate 31. In addition, the first mounting electrode 37 has a rectangular shape that substantially covers one surface of the bottom surface 32B of the base body 32, and a cathode mark (corner chipped portion) is provided at one corner portion.

The second mounting electrode 38 (anode) is provided on the other surface (surface in the −X direction in FIG. 2C) of the device substrate 31 that is divided by a line segment LY2 passing through the midpoint X2 and parallel to the short side of the device substrate 31. In addition, the second mounting electrode 38 has a rectangular shape that substantially covers the other surface of the bottom surface 32B of the base body 32.

As described above, the first element placing region 33B of the first wiring electrode 33 and the second element placing region 34B of the second wiring electrode 34 are spaced apart from each other by a wiring electrode separation band 48 along the line segment LX2. That is, the element electrodes 19 and 20 are provided to be spaced apart from each other in an extension direction (Y axis direction) of a line segment LY2 orthogonal to the line segment LX2. In addition, the first mounting electrode 37 and the second mounting electrode 38 are spaced apart from each other by a mounting electrode separation band 47 along the line segment LY2 orthogonal to the wiring electrode separation band 48. That is, the first mounting electrode 37 and the second mounting electrode 38 are provided to be spaced apart from each other in the extension direction (X axis direction) of the line segment LX2. In this manner, by making the wiring electrode separation band 48 of the element placing regions 33B and 34B and the mounting electrode separation band 47 of the mounting electrodes 37 and 38 orthogonal to each other, when the semiconductor light emitting element 10 is bonded and the light emitting device 30 is mounted on the circuit substrate, it is possible to prevent the device substrate 31 from being bent even when the device substrate 31 is made thin.

The first conduction via 35 (cathode) penetrates the base body 32 between the first land 33A of the first wiring electrode 33 and the first mounting electrode 37 up and down, and electrically connects both.

The second conduction via 36 (anode) penetrates the base body 32 between the second land 34A of the second wiring electrode 34 and the second mounting electrode 38 up and down, and electrically connects both.

Since the surfaces of the wiring electrodes 33 and 34 and the mounting electrodes 37 and 38 to which the conduction vias 35 and 36 are connected have irregularities, and the smoothness of the electrode surface is impaired, the conduction vias 35 and 36 are provided in portions other than the first element placing region 33B of the first wiring electrode 33 and the second element placing region 34B of the second wiring electrode 34.

The first wiring electrode 33, the second wiring electrode 34, the first mounting electrode 37, the second mounting electrode 38, the first conduction via 35, and the second conduction via 36 are made of a metal having copper (Cu) as a main component. In addition, the wiring electrode and the mounting electrode are plated with a Ni/Au layer on the surface thereof. As the main body metal of the wiring electrode, the mounting electrode, and the conduction via, tungsten (W) or the like is also able to be used.

### (Light Emitting Element)

The semiconductor light emitting element 10 is a flip chip including the first element electrode 19 and the second element electrode 20 having substantially the same size and rectangular shapes on a surface facing the element substrate 11, which is the light output surface. In addition, in the semiconductor light emitting element 10, each of the first element electrode 19 and the second element electrode 20, and each of the first element placing region 33B and the second element placing region 34B are connected to each other through the bonding member 41. The semiconductor light emitting element 10 including such element electrodes 19 and 20 has excellent self-alignment properties to the element placing regions 33B and 34B of the device substrate 31, and has low residual stress of the bonding. That is, even when the element substrate 11 or the device substrate 31 is thin, the bonding is able to be performed with good yield. The size of the semiconductor light emitting element 10 used in the present embodiment is a quadrangular shape having a side of approximately 1000 μm and a thickness of approximately 100 μm (thickness of the semiconductor light emitting element 10≈thickness of the element substrate 11). In consideration of ease of handling in the manufacturing step of the semiconductor light emitting element 10 having a thin thickness, it is preferable that the length of one side (line segment LX and line segment LY) is 600 μm to 1600 μm.

### (Protective Element)

As illustrated in FIGS. 2B and 2D, the protective element 39 is bonded to the protective element placing region 34C of the device substrate 31 through the bonding member 41. In addition, the upper electrode of the protective element 39 is electrically connected to the first land 33A by the conductive wire 40. The protective element 39 is connected in parallel to and in reverse polarity with the semiconductor light emitting element 10, and prevents the semiconductor light emitting element 10 from being damaged by static electricity or the like. A top portion of the wire 40 of the protective element 39 is lower than the total height (thickness) of the semiconductor light emitting element 10 and the phosphor plate 43.

Although a Zener diode is used as the protective element 39 of the present embodiment, a capacitor, a varistor, or the like is also able to be used as the protective element 39, in addition to the Zener diode.

### (Bonding Member)

As the bonding member 41, a gold-tin (Au-20 wt % Sn) alloy is used. A gold-tin cream solder is used for forming the gold-tin alloy. The flux contained in the gold-tin cream solder evaporates when the semiconductor light emitting element 10 and the protective element 39 are bonded to the device substrate 31. The surfaces of the element placing regions 33B and 34B to which the semiconductor light emitting element 10 is bonded are smooth, and the bonding members 41 are formed with a uniform thickness in a region where the element electrodes 19 and 20 of the semiconductor light emitting element 10 overlap the element placing regions 33B and 34B. As a result, the stress during the bonding applied to the thin semiconductor light emitting element 10 is able to be reduced, and the damage to the semiconductor light emitting element 10 is able to be prevented.

### (Phosphor Plate)

The phosphor plate 43 as a wavelength conversion member has a flat plate shape substantially the same size as the light output surface of the semiconductor light emitting element 10 in a top view. In addition, the phosphor plate 43 is a ceramic phosphor in which cerium-activated yttrium aluminum garnet (YAG: Ce) phosphor particles are contained in an alumina base material. As illustrated in FIG. 2B, the phosphor plate 43 is adhered to the top surface (+Z direction) of the element substrate 11 of the semiconductor light emitting element 10 through the adhesive member 42 made of a translucent silicone resin. The phosphor plate 43 absorbs a part or all of the blue light (primary light) emitted from the semiconductor light emitting element 10 and emits greenish yellow light (secondary light) which is longer in wavelength than the primary light. As a result, white light or greenish yellow light in which blue light (primary light) and greenish yellow light (secondary light) are mixed is emitted from the top surface of the phosphor plate 43 of the light emitting device 30.

The phosphor plate 43 may be smaller or larger than the light output surface of the semiconductor light emitting element 10. In addition, an uneven structure for reducing reflectivity, a translucent protective film for protecting the surface, a dielectric multi-layer film for controlling the orientation characteristics, or the like may be provided on the surface of the light incident surface (bottom surface) or the light output surface (top surface) of the phosphor plate 43. In addition, a reflective dielectric multi-layer film or a white ceramic film may be provided on the side surface.

As a base material of the phosphor plate 43, an inorganic material such as a translucent ceramic or glass, a translucent resin material, or the like is able to be used. In addition, the light conversion particles are not limited to the cerium-activated yttrium aluminum garnet (YAG: Ce) phosphor, cerium-activated lutetium aluminum garnet (LuAG: Ce) phosphor, europium and/or cerium-activated orthosilicate ((Ba, Sr, Ca) SiO₄: Eu, Ce) phosphor, cerium-activated terbium aluminum garnet (TAG: Ce), europium-activated α-sialon phosphor (α-SiAlON: Eu), europium-activated β-sialon phosphor (β-SiAlON: Eu), manganese-activated potassium fluorosilicate (KFS: Mn), or the like is able to be used, and different types of the light conversion particles are able to be appropriately selected and used depending on the wavelength of the excitation light, a desired color tone, and the like.

### (Coating Member)

As illustrated in FIGS. 2A and 2B, the coating member 44 extends outward of the phosphor plate 43 with the outer peripheral edge of the top surface of the phosphor plate 43 as a starting point, while the top surface of the phosphor plate 43 is exposed. In addition, the coating member 44 coats the top surface of the device substrate 31 and the side surfaces of the bonding member 41, the semiconductor light emitting element 10, the adhesive member 42, and the phosphor plate 43. That is, the semiconductor light emitting element 10 and the protective element 39 are sealed with the coating member 44. In addition, the top surface of the phosphor plate 43 is the light output surface of the light emitting device 30. In the present embodiment, since the element substrate 11 of the semiconductor light emitting element 10 is made thin, even when the device substrate 31 of the light emitting device 30 is made thin, the thickness of the coating member 44 is also made thin, and thus the occurrence of warping or the like of the light emitting device 30 due to the expansion and contraction of the coating member 44 is able to be suppressed.

As the coating member 44, a white resin obtained by dispersing reflective titanium oxide (TiO₂) fine particles in a medium of translucent silicone resin is used. As a translucent medium, an epoxy resin, an acrylic resin, a polycarbonate resin, a polystyrene resin, or the like is also able to be used. In addition, as the reflective fine particles, mixed ceramic particles of alumina (Al₂O₃) and zirconia (ZrO₂) is also able to be used.

### (Mounting on Circuit Substrate)

In the light emitting device 30 according to Embodiment 2, each of the first mounting electrode 37 and the second mounting electrode 38 is mounted on the circuit substrate through soldering. The wiring electrode separation band 48 between the first element placing region 33B and the second element placing region 34B of the light emitting device 30 is orthogonal to the mounting electrode separation band 47 between the first mounting electrode 37 and the second mounting electrode 38. Therefore, in the mounting of the light emitting device 30 on the circuit substrate, the stress of bending the linear portion in which the three hole portions 12A of the semiconductor light emitting element 10 are arranged is suppressed. As a result, even when the element substrate 11 and the device substrate 31 are thin, it is possible to prevent a malfunction such as a short-circuit of the light emitting device 30, and improve the reliability of the light emitting device 30.

### Comparative Example 2

Next, a light emitting device according to Comparative Example 2 will be described. The light emitting device according to Comparative Example 2 is a light emitting device in which the thickness of the element substrate 11 of the semiconductor light emitting element 10 of the light emitting device 30 according to Embodiment 2 is changed from 100 μm to 200 μm, and the other configurations are the same as those of

### Embodiment 2

### (Comparison of Light Output of Light Emitting Device)

The light emitting device 30 according to Embodiment 2 and the light emitting device according to Comparative Example 2 were bonded to a circuit substrate by soldering, and a current was passed through each light emitting device to compare the light output. As a result, in a case where the light output according to Comparative Example 2 was set to 100%, the light output according to Embodiment 2 was 108%. That is, the light output of the light emitting device 30 according to Embodiment 2 was increased by 8%. This is considered to be because a contact area between the element substrate 11 of the semiconductor light emitting element 10 and the coating member 44 is reduced. Similarly, when the element substrate 11 is thinned to 70 μm and 40 μm, the light output is increased. In this manner, the semiconductor light emitting element 10 according to Embodiment 1 used in the light emitting device 30 according to Embodiment 2 tends to decrease the light output in the single unit, but by using the light emitting device 30 according to Embodiment 2, the light emitting device 30 has high light output (luminous flux) characteristics. In addition, by thinning the light emitting device 30, it is possible to suppress light leakage from the side surface of the light emitting device 30 and to increase the light output from the light output surface of the light emitting device 30 (top surface of the phosphor plate 43).

Hereinbefore, according to the present invention, it is possible to provide the semiconductor light emitting element 10 in which a luminous flux is improved when used as the light emitting device 30, or the light emitting device 30 in which the reliability is improved and the luminous flux is improved while achieving thinning.

### (Method of Manufacturing Light Emitting Device)

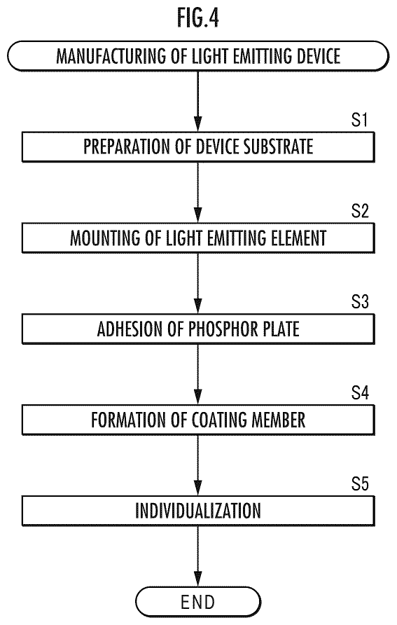

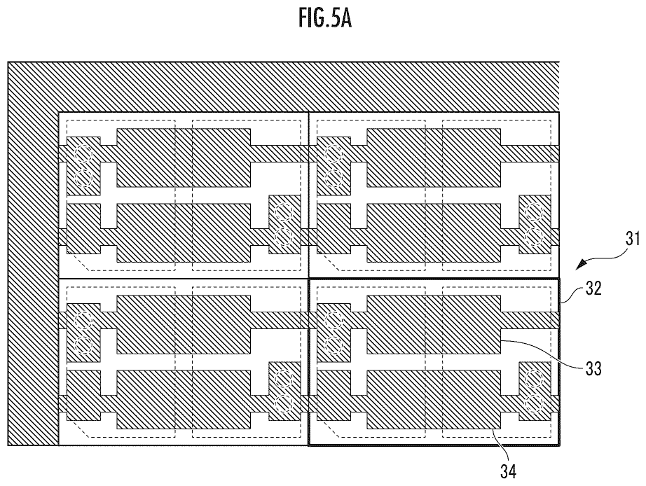

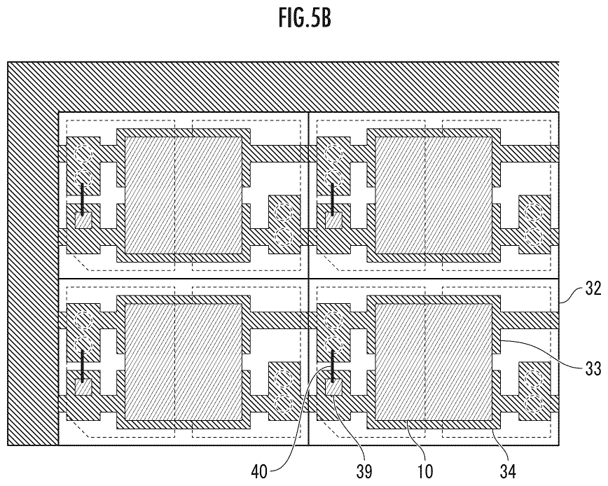

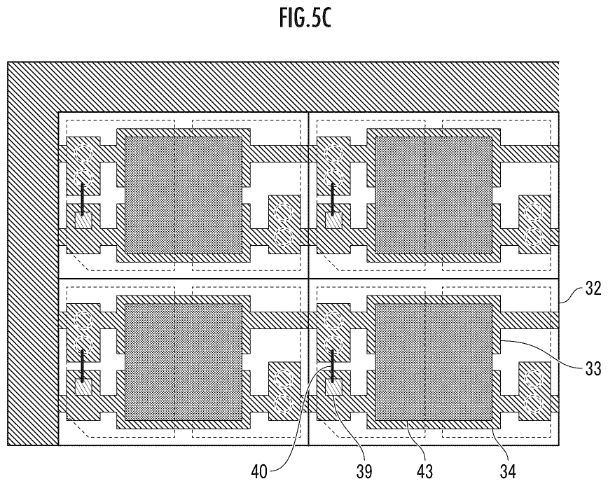

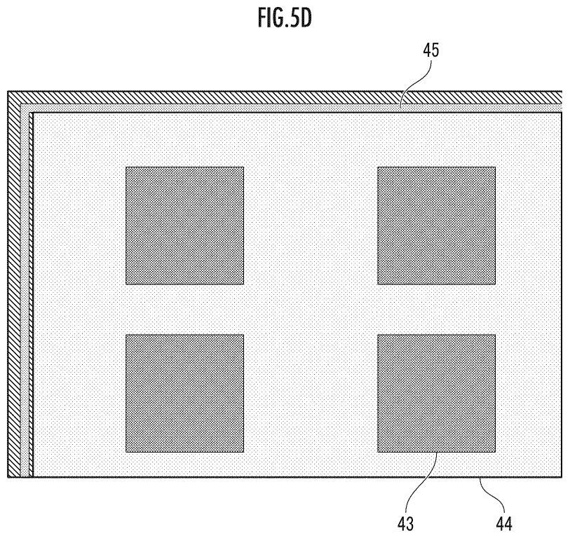

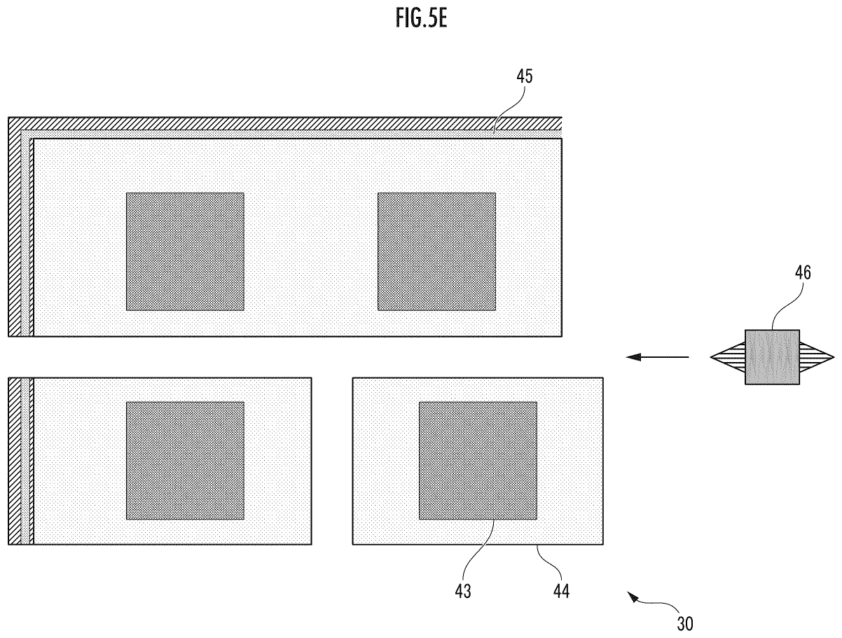

Hereinafter, a method of manufacturing a light emitting device 30 according to Embodiment 2 will be described in detail with reference to the flowchart and the drawings. FIG. 4 is a flowchart illustrating a method of manufacturing the light emitting device 30. In addition, FIGS. 5A to 5E are top views illustrating each of the steps.

### (S1) Preparation of Device Substrate

As the device substrate 31, a substrate in which the first wiring electrode 33, the second wiring electrode 34, the first conduction via 35, the second conduction via 36, the first mounting electrode 37, and the second mounting electrode 38 were provided on the base body 32 and a plurality of device substrates 31 for the light emitting device was integrated with each other was prepared (FIG. 5A). Hereinafter, in the description, the description of (S2) to (S4) is a description of the integrated substrate. An outer peripheral frame is provided on the outer periphery of the integrated substrate. In addition, a portion surrounded by a thick line in the drawing is one unit of the device substrate 31.

### (S2) Element Mounting Step

A gold-tin (Au—Sn) cream solder as the bonding member 41 was applied onto the first wiring electrode 33 and the second wiring electrode 34 on which the semiconductor light emitting element 10 and the protective element 39 were mounted. Next, the semiconductor light emitting element 10 and the protective element 39 were placed on the gold-tin cream solder.

Next, the semiconductor light emitting element 10 was heated to 300° C. in a reflow furnace to melt and solidify the gold-tin cream solder, and the semiconductor light emitting element 10 was mounted on the first wiring electrode 33 and the second wiring electrode 34. At the same time, the protective element 39 was also mounted on the second wiring electrode 34. Thereafter, the upper electrode of the protective element 39 and the first wiring electrode 33 were electrically connected to each other by a wire 40 (FIG. 5B).

### (S3) Phosphor Plate Adhesive Step

A silicone resin, which was a translucent adhesive agent, was applied to the top surface of the semiconductor light emitting element 10 as the adhesive member 42. Next, the phosphor plate 43 was placed on the semiconductor light emitting element 10. The adhesive member 42 was heated at 170° C. for 10 minutes to temporarily cure the silicone resin, and the phosphor plate 43 was adhered onto the semiconductor light emitting element 10 (FIG. 5C).

### (S4) Coating Member Forming Step

A frame body 45 was formed on the outer peripheral edge of the plurality of device substrates 31. The inside of the frame body 45 was filled with the coating member 44 made of silicone resin mixed with titanium oxide particles up to a height in contact with the outer peripheral edge of the top surface of the phosphor plate 43. Thereafter, the silicone resin was cured by heating at 100° C. for 30 minutes and at 150° C. for 1 hour. At this time, the adhesive member 42 was also main-cured (FIG. 5D).

### (S5) Individualization Step

The light emitting device 30 was cut for each unit with a dicing blade 46 and individualized. Through the above steps, the light emitting device 30 was manufactured (FIG. 5E).

### Embodiment 3

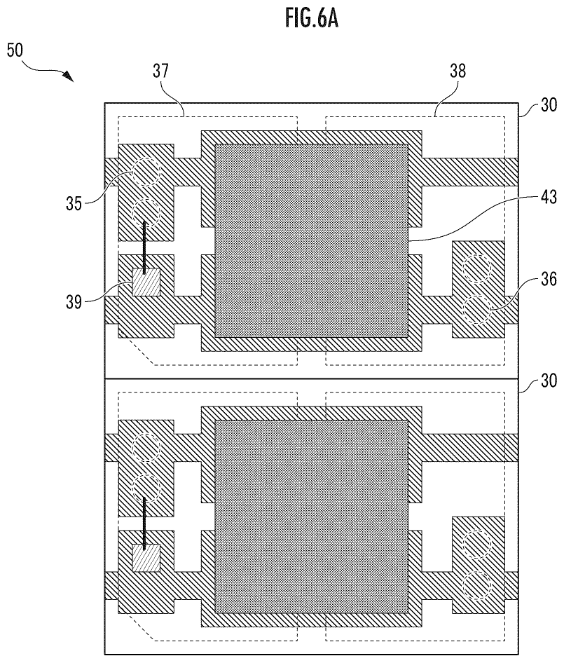

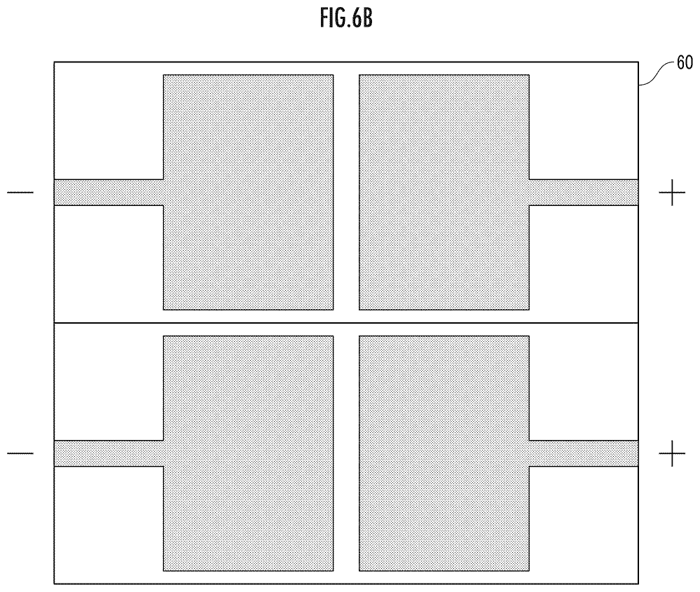

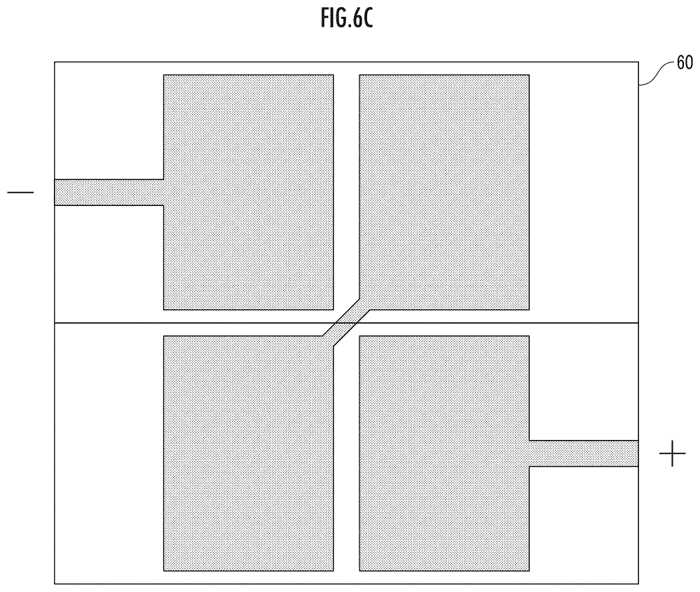

Next, a light emitting device 50 according to Embodiment 3 will be described. Description of the same configuration as that of the light emitting device 30 according to Embodiment 2 of the present invention will be omitted as appropriate. FIG. 6A is a plan view illustrating a top surface of the light emitting device 50 according to Embodiment 3, and is a view illustrating a state where the coating member 44 is made transparent (removed). FIG. 6B is a view illustrating a wiring pattern of the circuit substrate 60 on which the light emitting device 50 is mounted, and FIG. 6C is a view illustrating a modification example of a wiring pattern of the circuit substrate 60 on which the light emitting device 50 is mounted.

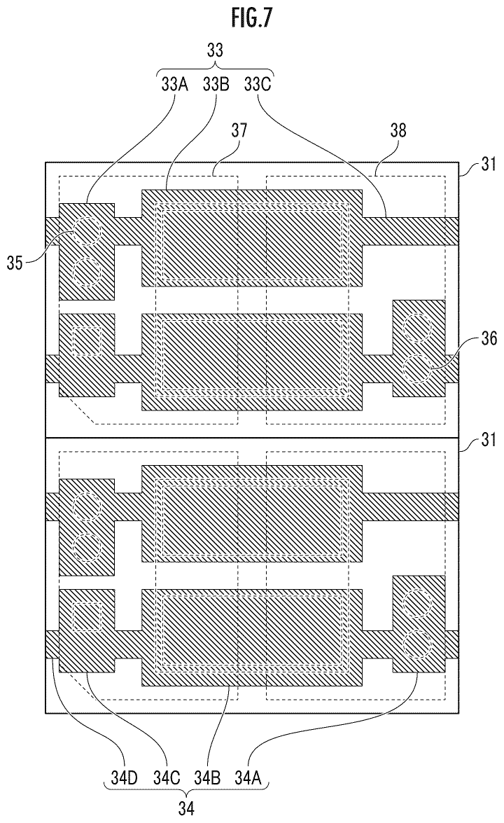

FIG. 7 is a plan view illustrating a top surface of a device substrate 31 of the light emitting device 50 according to Embodiment 3. In FIG. 6A, the first conduction via 35 and the second conduction via 36, and the first mounting electrode 37 and the second mounting electrode 38 are illustrated by broken lines in order to clarify the disposition relationship between the first conduction via 35 and the second conduction via 36, and the first mounting electrode 37 and the second mounting electrode 38. Furthermore, in FIG. 7, the first conduction via 35 and the second conduction via 36, and the first mounting electrode 37 and the second mounting electrode 38 are illustrated by broken lines in order to clarify the disposition relationship between the first element electrode 19 and the second element electrode 20, the first conduction via 35 and the second conduction via 36, and the first mounting electrode 37 and the second mounting electrode 38.

As illustrated in FIG. 6A, the light emitting device 50 according to Embodiment 3 is a plurality of unit type (here, two units) light emitting device having two light emitting devices 30 adjacent to each other. The light emitting device 50 is an aspect in which the light emitting device 30 according to Embodiment 2 is coupled in parallel in two units on the device substrate 31. Therefore, when the wiring pattern of the circuit substrate 60 is provided as illustrated in FIG. 6B, each of the light emitting elements (light emitting regions) of the light emitting device 50 is able to be individually driven.

In this manner, by driving the two light emitting devices 30 in parallel, the semiconductor light emitting elements 10 included in each of the light emitting devices 30 are able to be individually turned on. Therefore, for example, by making the wavelength conversion characteristics of the phosphor plate 43 included in the light emitting device 30 different from each other, it is possible to emit light of a plurality of colors with one light emitting device.

### Modification Example According to Embodiment 3

Next, a modification example of the light emitting device 50 according to Embodiment 3 is that, as illustrated in FIG. 6C, one set of an anode and a cathode are connected in series to the wiring pattern of the circuit substrate 60. In this manner, by driving the two light emitting devices 30 in series, the semiconductor light emitting elements 10 included in each of the light emitting devices 30 are able to be simultaneously turned on. Therefore, the luminous flux of the light emitting device is able to be further improved.

In the present embodiment, the number of the light emitting devices 30 included in the plurality of unit type light emitting device 50 is set to two, but may be three or more. In addition, as illustrated in FIG. 6A, in the present embodiment, the two light emitting devices 30 include the phosphor plate 43 individually for each semiconductor light emitting element 10, but one phosphor plate 43 may be provided for a plurality of the semiconductor light emitting elements 10.

As described above, according to the present invention, it is possible to provide the semiconductor light emitting element or the light emitting device in which the reliability is improved and the luminous flux is improved while achieving thinning.

### REFERENCE SIGNS LIST

10: semiconductor light emitting element
11: element substrate
12: light emitting semiconductor layer
13: n-type semiconductor layer
14: light emitting layer
15: p-type semiconductor layer
16: n-electrode
17: p-electrode
18: insulating film
19: first element electrode
20: second element electrode
30: light emitting device
31: device substrate
32: base body
33: first wiring electrode
34: second wiring electrode
35: first conduction via
36: second conduction via
37: first mounting electrode
38: second mounting electrode
39: protective element
40: wire
41: bonding member
42: adhesive member
43: phosphor plate
44: coating member
45: frame body
46: dicing blade
47: mounting electrode separation band
48: wiring electrode separation band
50: light emitting device
60: circuit substrate

What is claimed is:

1. A semiconductor light emitting element comprising:
a flat plate-shaped translucent element substrate that has two main surfaces facing each other;
a light emitting semiconductor layer configured to be formed on one main surface of the element substrate and in which an n-type semiconductor layer, a light emitting layer, and a p-type semiconductor layer are laminated;
an n-electrode configured to be connected to the n-type semiconductor layer through at least one hole portion leading to the n-type semiconductor layer and provided on the p-type semiconductor layer to be electrically separated from the p-type semiconductor layer by an insulating film;
a first element electrode configured to be electrically connected to the n-electrode and provided to extend in a first direction; and
a second element electrode configured to be electrically connected to the p-type semiconductor layer and provided to extend in the first direction while being spaced apart from the first element electrode,
wherein a thickness of the element substrate is 100 μm or less.

2. The semiconductor light emitting element according to claim 1,
wherein the thickness of the element substrate is 40 μm or more.

3. The semiconductor light emitting element according to claim 1,
wherein a thickness of the light emitting semiconductor layer is 3 to 5 μm.

4. The semiconductor light emitting element according to claim 1,
wherein the light emitting semiconductor layer has three or more hole portions, and
a plurality of the hole portions are arranged in a straight line at equal intervals.

5. A light emitting device comprising:
the semiconductor light emitting element according to claim 1; and
a device substrate that includes a base body having two planes facing each other and configured to be formed in a flat plate shape, a first wiring electrode and a second wiring electrode configured to be provided on one plane, a first mounting electrode configured to be provided on the other plane and connected to the first wiring electrode by a first conduction via penetrating the base body, and a second mounting electrode configured to be provided on the other plane and connected to the second wiring electrode by a second conduction via penetrating the base body, in which the semiconductor light emitting element is bonded onto the first wiring electrode and the second wiring electrode through a bonding member,
wherein the first element electrode and the second element electrode are disposed to be spaced apart from each other in a second direction orthogonal to the first direction, and
the first mounting electrode and the second mounting electrode are disposed to be spaced apart from each other in the first direction.

6. The light emitting device according to claim 5,
wherein the first element electrode and the second element electrode are disposed to be spaced apart from each other in the second direction from a midpoint of the device substrate, and
the first mounting electrode and the second mounting electrode are disposed to be spaced apart from each other in the first direction from the midpoint of the device substrate.

7. The light emitting device according to claim 5,
wherein the first wiring electrode has a first element placing region on which the first element electrode is placed and a first land on which the first conduction via is disposed,
the second wiring electrode has a second element placing region on which the second element electrode is placed and a second land on which the second conduction via is disposed, and
the first land and the second land are each disposed to be spaced from the first element placing region and the second element placing region in the first direction.

8. The light emitting device according to claim 5,
wherein the element substrate is made of a sapphire single crystal, and
the base body of the device substrate is made of an aluminum nitride-based ceramic.

9. The light emitting device according to claim 5,
wherein a thickness of the base body is 30 μm to 120 μm.

10. A plurality of unit type light emitting device comprising:
a plurality of the light emitting devices according to claim 5,
wherein the plurality of light emitting devices is disposed adjacent to each other and is electrically connected in series or in parallel to each other.

11. The light emitting device according to claim 10, further comprising:
a phosphor plate configured to adhere onto a plurality of the semiconductor light emitting elements through an adhesive member,
wherein the phosphor plate is formed integrally.
